(19) United States
(12) Patent Application Publication
(10) Pub. No.: US 2025/0029958 A1
(43) Pub. Date: Jan. 23, 2025

(54) PACKAGED INTEGRATED CIRCUIT, BIDIRECTIONAL DATA TRANSMISSION METHOD, AND CONTROL SYSTEM

(71) Applicant: Nuvoton Technology Corporation, Hsinchu Science Park (TW)

(72) Inventors: Chih-Hsien YANG, Hsinchu City (TW); Chieh-Sheng TU, Hsinchu Science Park (TW)

(21) Appl. No.: 18/760,438

(22) Filed: Jul. 1, 2024

(30) Foreign Application Priority Data
Jul. 20, 2023 (TW) 112127015

(51) Int. Cl. H01L 25/07; H01L 23/00; H01L 23/538

(52) U.S. Cl. CPC H01L 25/072; H01L 23/538; H01L 24/08; H01L 2224/08225; H01L 2924/14252; H01L 2924/1427

(57) ABSTRACT

A packaged integrated circuit including an input-output pin, a first chip and a second chip is provided. The first chip includes a first voltage converter circuit, a second voltage converter circuit, and a data transmission circuit. The first voltage converter circuit, the second voltage converter circuit, and the data transmission circuit are connected in parallel between an internal pin and the input-output pin. The second chip enables the first voltage converter circuit, the second voltage converter circuit, or the data transmission circuit based on the operation mode of the internal pin.

### CROSS REFERENCE TO RELATED APPLICATIONS

This Application claims priority of Taiwan Patent Application No. 112127015, filed on Jul. 20, 2023, the entirety of which is incorporated by reference herein.

### BACKGROUND OF THE INVENTION

### Field of the Invention

The present invention relates to an integrated circuit, and, in particular, to a packaged integrated circuit that combines a plurality of chips.

### Description of the Related Art

In general, when a specific input-output pin of a packaged integrated circuit is used as an input pin or an output pin, the packaged integrated circuit only uses the specific input-output pin to perform unidirectional signal transmission. The packaged integrated circuit cannot transmit electrical signals with analog characteristics.

### BRIEF SUMMARY OF THE INVENTION

In accordance with an embodiment of the disclosure, a packaged integrated circuit comprises an input-output pin, a first chip, and a second chip. The first chip comprises a first internal pin, a second internal pin, a first voltage conversion circuit, a second voltage conversion circuit, and a data transmission circuit. The first internal pin is electrically connected to the input-output pin. The first voltage conversion circuit converts the voltage level of the first internal pin to generate a first converted level and provides the first converted level to the second internal pin. The second voltage conversion circuit converts the voltage level of the second internal pin to generate a second converted level and provides the second converted level to the first internal pin. The data transmission circuit provides a transmission path between the first internal pin and the second internal pin. The second chip comprises a third internal pin, a storage circuit, and a processing circuit. The third internal pin is electrically connected to the second internal pin. The storage circuit is configured to store program code. The processing circuit executes the program code to set an operation mode of the third internal pin and enables the first voltage conversion circuit, the second voltage conversion circuit, or the data transmission circuit based on the operation mode of the third internal pin.

A bidirectional data transmission method applied in a packaged integrated circuit is provided. The packaged integrated circuit comprises an input-output pin. An exemplary embodiment of a bidirectional data transmission method is described in the following paragraph. Program code is executed to generate an execution result. The program code is stored in a storage circuit. The operation mode of an internal pin is set based on the execution result. A first voltage conversion circuit is enabled to convert the voltage level of the input-output pin in response to the operation mode of the internal pin being a first mode. A second voltage conversion circuit is enabled to convert the voltage level of the input-output pin in response to the operation mode of the internal pin being a second mode. A data transmission circuit is enabled to form a transmission path between the internal pin and the input-output pin in response to the operation mode of the internal pin being a third mode. The first voltage conversion circuit, the second voltage conversion circuit and the data transmission circuit are coupled between the internal pin and the input-output pin.

In accordance with another embodiment of the disclosure, a control system comprises an external device and a packaged integrated circuit. The packaged integrated circuit is coupled to the external device and comprises an input-output pin, a micro-controller chip, and a voltage conversion chip. The input-output pin is electrically connected to the external device. The micro-controller chip comprises an internal pin. The voltage conversion chip comprises a first path, a second path, and a third path. The first path, the second path, and the third path are connected in parallel between the internal pin and the input-output pin. In response to the internal pin serving as an input pin, the micro-controller chip turns on the first path. In response to the internal pin serving as an output pin, the micro-controller chip turns on the second path. In response to the voltage level of the internal pin being in a floating state, the micro-controller chip turns on the third path.

Methods of bidirectional data transmission may be practiced by a micro-controller chip and a packaged integrated circuit which have hardware or firmware capable of performing particular functions and may take the form of program code embodied in a tangible media. When the program code is loaded into and executed by an electronic device, a processor, a computer or a machine, the electronic device, the processor, the computer or the machine becomes a micro-controller chip and a packaged integrated circuit for practicing the disclosed method.

### BRIEF DESCRIPTION OF THE DRAWINGS

The present invention can be more fully understood by reading the subsequent detailed description and examples with references made to the accompanying drawings, wherein:

FIG. 1 is a schematic diagram of an exemplary embodiment of a packaged integrated circuit based on various aspects of the present disclosure.

FIG. 2 is a flowchart of a control method for performing bidirectional data transmission in accordance with an embodiment of the present disclosure.

FIG. 3 is a schematic diagram of an exemplary embodiment of a control system based on various aspects of the present disclosure.

### DETAILED DESCRIPTION OF THE INVENTION

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

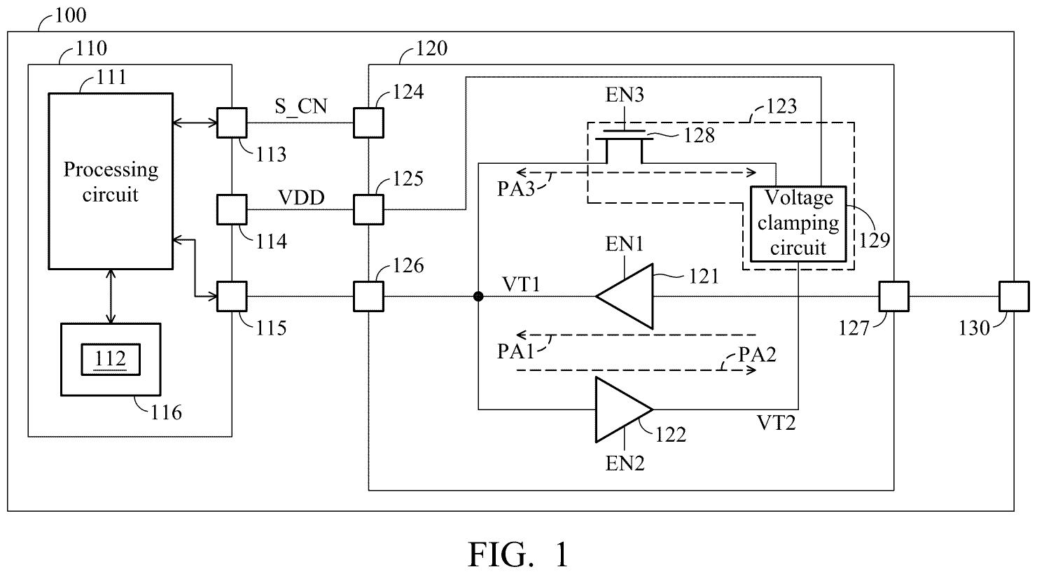

FIG. 1 is a schematic diagram of an exemplary embodiment of a packaged integrated circuit based on various aspects of the present disclosure. The packaged integrated circuit 100 comprises a micro-controller chip 110, a voltage conversion chip 120, and an input-output pin 130. In one embodiment, the micro-controller chip 110 and the voltage conversion chip 120 are packaged together to form the packaged integrated circuit 100. Additionally, the micro-controller chip 110 and the voltage conversion chip 120 communicate with an external device (not shown) via the input-output pin 130. In one embodiment, the input-output pin 130 is a general purpose input-output (GPIO) pin.

The micro-controller chip 110 comprises at least one internal pin 115. In one embodiment, the micro-controller chip 110 executes the program code 112 to set the operation mode of the internal pin 115. Additionally, the micro-controller chip 110 generates at least one pieces of control data S_CN based on the operation mode of the internal pin 115. In one embodiment, the micro-controller chip 110 further comprises an internal pin 113 to output the control data S_CN. The format of control data S_CN is not limited in the present disclosure. In one embodiment, the control data S_CN is serial data. In another embodiment, the control data S_CN is parallel data. In this case, the micro-controller chip 110 transmits the control data S_CN via a plurality of internal pins.

In another embodiment, the micro-controller chip 110 receives an operation voltage VDD. The source of the operation voltage VDD is not limited in the present disclosure. In one embodiment, a power supply device (not shown) disposed outside of the packaged integrated circuit 100 provides the operation voltage VDD to the micro-controller chip 110. In this case, the packaged integrated circuit 100 further comprises a second input-output pin (not shown) to receive the operation voltage VDD. Additionally, the micro-controller chip 110 further comprises an internal pin (not shown) to receive the operation voltage VDD from the second input-output pin. In another embodiment, the operation voltage VDD is provided by the voltage conversion chip 120. In this case, the voltage conversion chip 120 comprises a power supply device (not shown) to generate the operation voltage VDD. In this case, the micro-controller chip 110 further comprises an internal pin 114 to receive the operation voltage VDD from the voltage conversion chip 120.

The circuit structure of micro-controller chip 110 is not limited in the present disclosure. In one embodiment, the micro-controller chip 110 comprises a processing circuit 111 and a storage circuit 116. The storage circuit 116 stores the program code 112. The structure of the storage circuit 116 is not limited in the present disclosure. In one embodiment, the storage circuit 116 comprises a non-volatile memory.

The processing circuit 111 reads the storage circuit 116 and executes the program code 112. After executing the program code 112, the processing circuit 111 sets the operation mode of the internal pin 115. Furthermore, the processing circuit 111 generates the control data S_CN based on the operation mode of the internal pin 115. In another embodiment, after the operation voltage VDD is stable (e.g., the operation voltage VDD arrives a target voltage), the processing circuit 111 and the storage circuit 116 start operating. The number of internal pins of the micro-controller chip 110 is not limited in the present disclosure. The micro-controller chip 110 may comprise more internal pins to receive signals from outside of the packaged integrated circuit 100. In this case, the packaged integrated circuit 100 comprises more input-output pins. The more input-output pins receive external signals and provide the external signals to the micro-controller chip 110.

In one embodiment, the voltage conversion chip 120 comprises paths PA1˜PA3. The paths PA1˜PA3 are connected in parallel between the internal pin 115 and the input-output pin 130. In this case, the voltage conversion chip 120 comprises internal pins 126 and 127. The internal pin 126 is directly electrically connected to the internal pin 115 and the paths PA1˜PA3. The internal pin 127 is directly electrically connected to the input-output pin 130 and the paths PA1˜PA3.

When the processing circuit 111 sets the operation mode of the internal pin 115 to an input mode, this indicates that the internal pin 115 serves as an input pin. Therefore, the processing circuit 111 turns on the path PA1 via the control data S_CN and receives the signals or the voltages from the internal pin 126. In one embodiment, the control data S_CN comprises control bits EN1˜EN3.

In an embodiment, the path PA1 comprises a voltage conversion circuit 121. The voltage conversion circuit 121 is coupled between the internal pins 126 and 127 and operates based on the control bit EN1. For example, when the value of the control bit is a specific value (e.g., the value 1), the voltage conversion circuit 121 starts converting the voltage level of the internal pin 127 (or the voltage level of the input-output pin 130) to generate a converted level VT1. The voltage conversion circuit 121 outputs the converted level VT1 to the internal pin 126. When the value of the control bit EN1 is not equal to the specific value, the voltage conversion circuit 121 stops converting the voltage level of the internal pin 127.

The structure of voltage conversion circuit 121 is not limited in the present disclosure. The voltage conversion circuit 121 converts the voltage level of the internal pin 127 to an appropriate voltage level for the micro-controller chip 110 and provides the appropriate voltage level to the internal pin 126. For example, the voltage conversion circuit 121 converts the voltage level of the input-output pin 130 from a logic level or a voltage domain into another logic level or another voltage domain.

When the processing circuit 111 sets the operation mode of the internal pin 115 to an output mode, this indicates that the internal pin 115 is serving as an output pin. The processing circuit 111 uses the control data S_CN to turn on the path PA2 and outputs data or voltages to the internal pin 126 via the path PA2.

In one embodiment, the path PA2 comprises a voltage conversion circuit 122. The voltage conversion circuit 122 operates based on the control bit EN2. For example, when the value control bit EN2 is equal to a specific value (e.g., 1), the voltage conversion circuit 122 converts the voltage level of the internal pin 126 (or the voltage level of the internal pin 115) to generate a converted level VT2. The voltage conversion circuit 122 outputs the converted level VT2 to the internal pin 127. When the value of the control bit EN2 is not equal to the specific value, the voltage conversion circuit 122 stops converting the voltage level of the internal pin 126.

The structure of voltage conversion circuit 122 is not limited in the present disclosure. The voltage conversion circuit 122 converts the voltage level of the internal pin 115 to an appropriate voltage level for an external device (not shown) and provides the appropriate voltage level to the input-output pin 130. In one embodiment, the voltage conversion circuit 122 converts the voltage level of the internal pin 115 from a logic level or a voltage domain into another logic level or another voltage domain.

In another embodiment, each of the voltage conversion circuit 121 and the voltage conversion circuit 122 serves as a bridge and is coupled between a high-voltage element and a low-voltage element (e.g., the micro-controller chip 110). Taking the voltage conversion circuit 121 as an example, the voltage conversion circuit 121 may convert the voltage level of the internal pin 127 from 20V to 5V and then output the converted result 5V to the storage circuit 116. Additionally, the voltage conversion circuit 122 may convert the voltage level of the internal pin 126 from 5V to 20V and then outputs the converted result 20V to the internal pin 127.

When the processing circuit 111 sets the operation mode of the internal pin 115 to a bidirectional input-output mode, an open-drain mode, or a tri-state mode, this indicates that the voltage level of the internal pin 115 may be in a floating state or a high-impedance state. At this time, the micro-controller chip 110 turns on the path PA3. In one embodiment, the path PA3 comprises a data transmission circuit 123.

The data transmission circuit 123 operates based on the control bit EN3. For example, when the value of the control bit EN3 is equal to a specific value (e.g., 1), the data transmission circuit 123 is turned on to transmit the voltage level of the input-output pin 130 to the internal pin 115 or transmit the voltage level of the internal pin 115 to the input-output pin 130. When the value of the control bit EN3 is not equal to the specific value, the data transmission circuit 123 is turned off.

When the micro-controller chip 110 directs the voltage conversion chip 120 to perform a voltage conversion operation, although the path PA1 and the path PA2 are unidirectional paths, the path PA3 is a bidirectional path. Therefore, the micro-controller chip 110 can communicate the external device (not shown) which is coupled to the input-output pin 130. In one embodiment, the path PA3 serves as a transmission path. The kind of communication protocol between the micro-controller chip 110 and the external device is not limited in the present disclosure. In one embodiment, the micro-controller chip 110 utilizes an inter-integrated circuit (I2C) protocol to communicate with the external device which is coupled to the input-output pin 130.

The structure of the data transmission circuit 123 is not limited in the present disclosure. In one embodiment, the data transmission circuit 123 comprises a transmission gate 128. The transmission gate 128 is coupled to the internal pins 126 and 127. When the processing circuit 111 uses the control bit EN3 to enable the transmission gate 128, the transmission gate 128 is turned on to provide the path PA3. When the processing circuit 111 disables the transmission gate 128, the transmission gate 128 stops providing the path PA3. At this time, the path PA3 is treated as an open state.

In another embodiment, the data transmission circuit 123 further comprises a voltage clamping circuit 129. The voltage clamping circuit 129 is coupled between the transmission gate 128 and the internal pin 127 and limits the voltage level of the transmission gate 128 to lower than a threshold value. For example, when the voltage level of the internal pin 127 is higher than a threshold value, the voltage clamping circuit 129 outputs a specific voltage to the transmission gate 128. When the voltage level of the internal pin 127 is not higher than a threshold value, the voltage clamping circuit 129 directly outputs the voltage level of the internal pin 127 to the transmission gate 128.

The structure of the voltage clamping circuit 129 is not limited in the present disclosure. In one embodiment, the voltage clamping circuit 129 comprises a Zener diode. In another embodiment, the voltage clamping circuit 129 is coupled to the internal pin 125 to receive the operation voltage VDD. In this case, the voltage clamping circuit 129 may use the operation voltage VDD as a threshold value. When the voltage level of the internal pin 127 is higher than the operation voltage VDD, the voltage clamping circuit 129 continually outputs a specific voltage. The specific voltage may be equal to the operation voltage VDD or may be slightly less than the operation voltage VDD.

In an embodiment, the voltage conversion chip 120 further comprises a first power supply circuit (not shown). The first power supply circuit converts an external voltage (which may be provided by an external power supply circuit disposed outside of the packaged integrated circuit 100) to generate the operation voltage VDD and outputs the operation voltage VDD to the micro-controller chip 110 via the internal pin 125. In this case, the first power supply circuit directly provides the operation voltage VDD to the power clamping circuit 129.

In another embodiment, the voltage conversion chip 120 further comprises a second power supply circuit (not shown). The second power supply circuit converts an external voltage (which may be provided by an external power supply circuit disposed outside of the packaged integrated circuit 100) to generate a second operation voltage and provides the second operation voltage to the voltage conversion circuit 121 and the voltage conversion circuit 122, and the data transmission circuit 123. In one embodiment, the second operation voltage is higher than the operation voltage VDD. In another embodiment, an external power supply circuit which is disposed outside of the packaged integrated circuit 100 provides the second operation voltage to the voltage conversion chip 120. In this case, the voltage conversion chip 120 receives the second operation voltage via another internal pin (not shown).

In another embodiment, the voltage conversion chip 120 further comprises a storage circuit (not shown) to store the control data S_CN. For example, the storage circuit may comprise three registers to store the control bits EN1˜EN3, respectively. In another embodiment, the control data S_CN may have more or fewer control bits.

In one embodiment, when the internal pin 115 operates in an input mode, the processing circuit 111 uses the control bit EN1 to enable the voltage conversion circuit 121, uses the control bit EN2 to disable the voltage conversion circuit 122, and uses the control bit EN3 to disable the data transmission circuit 123. Therefore, the internal pin 115 receives the signals from the input-output pin 130. When the internal pin 115 operates in an output mode, the processing circuit uses the control bit EN2 to enable the voltage conversion circuit 122, uses the control bit EN1 to disable the voltage conversion circuit 121, and uses the control bit EN3 to disable the data transmission circuit 123. Therefore, the internal pin 115 outputs signals to the input-output pin 130. When the internal pin 115 operates in a bidirectional input-output mode, an open-drain mode, or a tri-state mode, the processing circuit uses the control bit EN3 to enable the data transmission circuit 123, uses the control bit EN1 to disable the voltage conversion circuit 121, and uses the control bit EN2 to disable the voltage conversion circuit 122. Therefore, the internal pin 115 may receive signals from the input-output pin 130 or output signals to the input-output pin 130.

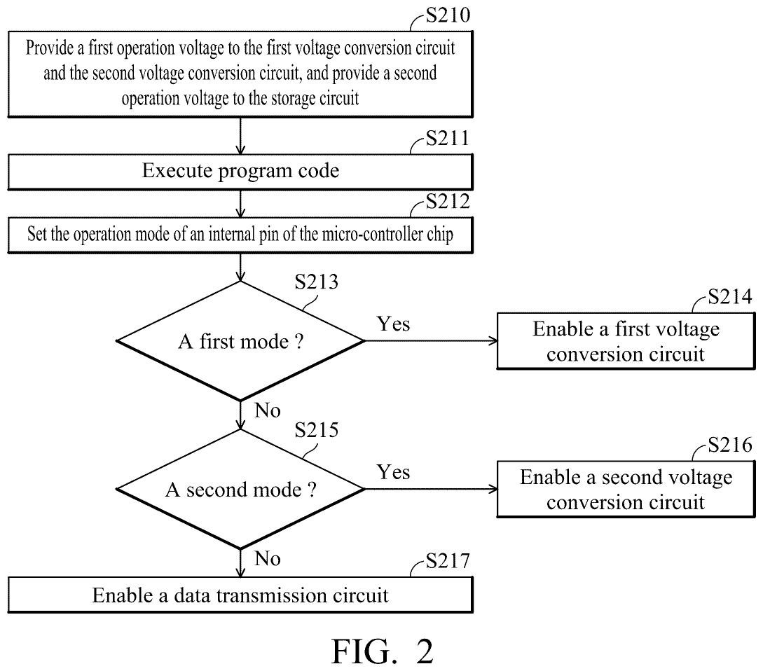

FIG. 2 is a flowchart of a control method for performing bidirectional data transmission in accordance with an embodiment of the present disclosure. Bidirectional data transmission control methods may take the form of program code. When the program code is loaded into and executed by a machine, the machine thereby becomes a micro-controller chip for practicing the methods. The bidirectional data transmission control method is applied in a packaged integrated circuit. The packaged integrated circuit comprises an input-output pin.

First, program code is executed to generate an execution result (step S211). In one embodiment, the program code is stored in a storage circuit and executed by a micro-controller chip.

The operation mode of an internal pin of the micro-controller chip is set based on the execution result (step S212). Then, a determination is made as to whether the operation mode of the internal pin is a first mode (step S213). In one embodiment, step S213 is performed to determine whether the operation mode of the internal pin is an input mode. When the operation mode of the internal pin is an input mode, a first voltage conversion circuit is enabled to convert the voltage level of the input-output pin (step S214). In one embodiment, the first voltage conversion circuit is coupled between the internal pin and the input-output pin. In this case, the first voltage conversion circuit provides the converted level to the internal pin.

When the operation mode of the internal pin is not the first mode, a determination is made as to whether the operation mode of the internal pin is a second mode (step S215). The second mode is different from the first mode. In one embodiment, step S215 is performed to determine whether the operation mode of the internal pin is an output mode. When the operation mode of the internal pin is an output mode, a second voltage conversion circuit is enabled to convert the voltage level of the internal pin (step S216). In one embodiment, the second voltage conversion circuit is coupled between the internal pin and the input-output pin. In this case, the second voltage conversion circuit provides the converted level to the input-output pin.

When the operation mode of the internal pin is not the second mode, this indicates that the operation mode of the internal pin is a bidirectional input-output mode, an open-drain mode, or a tri-state mode. Therefore, a data transmission circuit is enabled to form a transmission path between the internal pin and the input-output pin (step S217). In one embodiment, the data transmission circuit is coupled between the internal pin and the input-output pin. In this case, when the data transmission circuit is enabled, the data transmission circuit provides a transmission path between the internal pin and the input-output pin. At this time, the data transmission circuit may transmit the voltage level of the internal pin to the input-output pin or transmit the voltage level of the input-output pin to the internal pin.

In an embodiment, the data transmission circuit comprises a transmission gate and a voltage clamping circuit. When the data transmission circuit is enabled, the transmission gate is turned on. The voltage clamping circuit is configured to ensure that the voltage entering the transmission gate is lower than a threshold value. In one embodiment, the voltage clamping circuit compares the voltage level of the internal pin and a threshold value. When the voltage level of the internal pin is higher than the threshold value, the voltage clamping circuit outputs a specific voltage to the transmission gate. When the voltage level of the internal pin is not higher than the threshold value, the voltage clamping circuit directly outputs the voltage level of the internal pin to the transmission gate.

In another embodiment, the method shown in FIG. 2 further comprises a step S210 before the step S211. The step S210 is performed to provide a first operation voltage to the first voltage conversion circuit and the second voltage conversion circuit, and provide a second operation voltage to the storage circuit storing the program code. In one embodiment, the first operation voltage is higher than the second operation voltage. In another embodiment, when the data transmission circuit is enabled, the voltage clamping circuit of the data transmission circuit uses the second operation voltage as a threshold value. In another embodiment, the voltage clamping circuit sets the threshold value based on the second operation voltage. For example, the voltage clamping circuit may set the threshold value slightly higher than the second operation voltage.

In an embodiment, the step S214 is performed to enable the first voltage conversion circuit and disable the second voltage conversion circuit and the data transmission circuit. Therefore, when the first voltage conversion circuit operates, the second voltage conversion circuit and the data transmission circuit stop operating. Additionally, step S216 is performed to enable the second voltage conversion circuit and disable the first voltage conversion circuit and the data transmission circuit. Therefore, when the second voltage conversion circuit operates, the first voltage conversion circuit and the data transmission circuit stop operating. Furthermore, step S217 is performed to enable the data transmission circuit and disable the first voltage conversion circuit and the second voltage conversion circuit. Therefore, when the data transmission circuit operates, the first voltage conversion circuit and the second voltage conversion circuit stop operating.

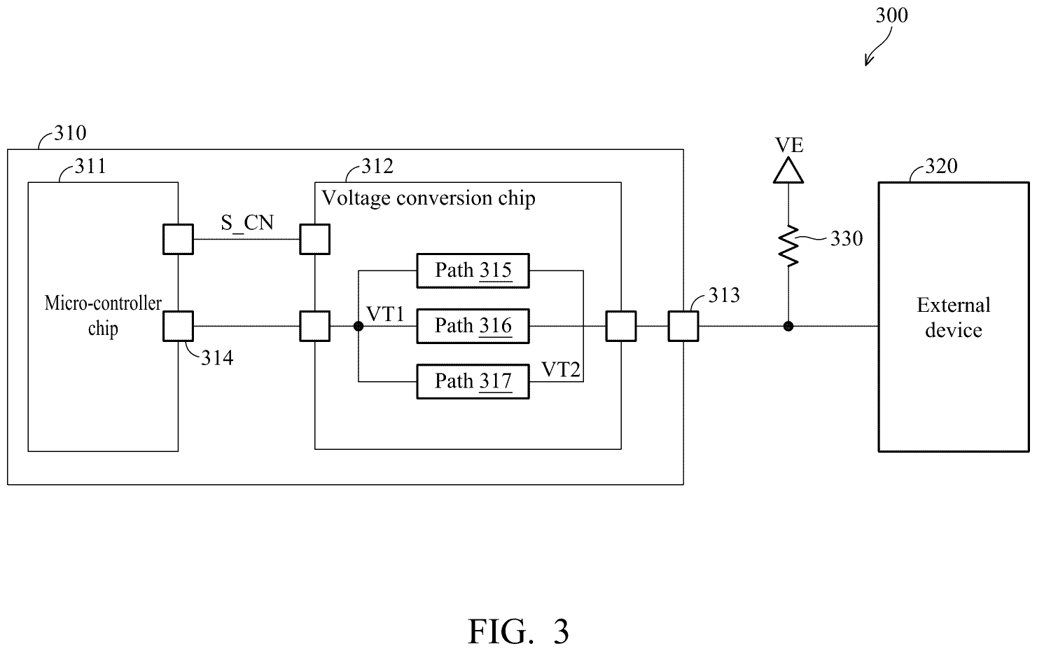

FIG. 3 is a schematic diagram of an exemplary embodiment of a control system based on various aspects of the present disclosure. As shown in FIG. 3, the control system 300 comprises a packaged integrated circuit 310 and an external device 320. The packaged integrated circuit 310 is coupled to the external device 320 and comprises a micro-controller chip 311, a voltage conversion chip 312 and an input-output pin 313. The micro-controller chip 311 comprises an internal pin 314. The voltage conversion chip 312 comprises paths 315˜317. Since the characteristics of the micro-controller chip 311, the voltage conversion chip 312, and the input-output pin 313 are similar to the characteristics of the micro-controller chip 110, the voltage conversion chip 120, and the input-output pin 130 shown in FIG. 1, the related description is omitted here.

When the internal pin 314 serves as an input pin, the micro-controller chip 311 uses the control data S_CN to turn on the path 316. In one embodiment, the path 316 comprises a voltage conversion circuit (now shown in FIG. 3). The first voltage conversion circuit converts the voltage level of the input-output pin 313 to generate a converted level VT1 and provides the converted level VT1 to the internal pin 314.

When the internal pin 314 is used as an output pin, the micro-controller chip 311 turns on the path 317 via the control data S_CN. In one embodiment, path 317 comprises a second voltage conversion circuit (not shown in FIG. 3). The second voltage conversion circuit converts the voltage level of the internal pin 314 to generate a converted level VT2 and outputs the converted level VT2 to the input-output pin 313.

When the internal pin 314 operates in a bidirectional input-output mode, an open-drain mode, or a tri-state mode, the micro-controller chip 311 turns on the path 315 via the control data S_CN. In one embodiment, the path 315 comprises a data transmission circuit (not shown). The data transmission circuit is configured to transmit the voltage level of the input-output pin 313 to the internal pin 314 or transmit the voltage level of the internal pin to the input-output pin 313.

In another embodiment, when the micro-controller chip 311 turns on the path 316, the micro-controller chip 311 turns off the path 315 and the path 317. In this case, when the micro-controller chip 311 turns on the path 317, the micro-controller chip 311 turns off the path 315 and the path 316. When the micro-controller chip 311 turns on the path 315, the micro-controller chip 311 turns off the path 316 and the path 317.

The external device 320 is electrically connected to the input-output pin 313. The external device 320 may receive the electrical characteristics from the input-output pin 313, such as signals, voltage levels, currents. In another embodiment, the external device 320 outputs the corresponding electrical characteristics, such as signals, voltage levels, and currents to the packaged integrated circuit 310. The kin of external device 320 is not limited in the present disclosure. In one embodiment, the external device 320 is a motor device.

In another embodiment, the control system 300 further comprises a pull-high resistor 330. The pull-high resistor 330 is coupled to the input-output pin 313 and the external device 320 and receives an external voltage VE. When the micro-controller chip 311 sets the operation mode of the input-output pin 313 to a bidirectional input-output mode, an open-drain mode, or a tri-state mode, the external device 320 receives a high level by the pull-high resistor 330. In one embodiment, when the external device 320 is not ready, the external device may pull-down the voltage level of the input-output pin 313 to a low level. The micro-controller chip 311 obtains that the external device 320 is not ready based on the voltage level of the input-output pin 313. Therefore, the micro-controller chip 311 may wait for a time interval and then determines whether the external device 320 is ready based on the voltage level of the input-output pin 313.

Since the path 315 is capable of performing bidirectional transmission, when the micro-controller chip 311 sets the voltage level of the internal pin 314 at a floating level or a high impedance state, the micro-controller chip 311 can obtain whether the external device 320 is ready based on the voltage level of the internal pin 314. Therefore, the performance of the packaged integrated circuit 310 is greatly increased.

Bidirectional data transmission methods, or certain aspects or portions thereof, may take the form of program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes a micro-controller chip and a packaged integrated circuit for practicing the methods. The methods may also be embodied in the form of program code transmitted over some transmission medium, such as electrical wiring or cabling, through fiber optics, or via any other form of transmission, wherein, when the program code is received and loaded into and executed by a machine such as a computer, the machine becomes a micro-controller chip and a packaged integrated circuit for practicing the disclosed methods. When implemented on a general-purpose processor, the program code combines with the processor to provide a unique apparatus that operates analogously to application-specific logic circuits.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A packaged integrated circuit, comprising:
an input-output pin;
a first chip, comprising:
a first internal pin electrically connected to the input-output pin;
a second internal pin;
a first voltage conversion circuit converting a voltage level of the first internal pin to generate a first converted level and providing the first converted level to the second internal pin;
a second voltage conversion circuit converting a voltage level of the second internal pin to generate a second converted level and providing the second converted level to the first internal pin; and
a data transmission circuit providing a transmission path between the first internal pin and the second internal pin; and
a second chip comprising:
a third internal pin electrically connected to the second internal pin;
a storage circuit configured to store program code; and
a processing circuit executing the program code to set an operation mode of the third internal pin and enabling the first voltage conversion circuit, the second voltage conversion circuit, or the data transmission circuit based on the operation mode of the third internal pin.

2. The packaged integrated circuit as claimed in claim 1, wherein in response to the processing circuit setting the operation mode of the third internal pin to a first mode, the processing circuit enables the first voltage conversion circuit.

3. The packaged integrated circuit as claimed in claim 2, wherein in response to the processing circuit setting the operation mode of the third internal pin to a second mode, the processing circuit enables the second voltage conversion circuit.

4. The packaged integrated circuit as claimed in claim 3, wherein in response to the processing circuit setting the operation mode of the third internal pin to a third mode, the processing circuit enables the data transmission circuit.

5. The packaged integrated circuit as claimed in claim 1, wherein the data transmission circuit comprises:
a transmission gate coupled between the first internal pin and the second internal pin to provide the transmission path.

6. The packaged integrated circuit as claimed in claim 5, wherein the data transmission circuit further comprises:
a voltage clamping circuit coupled between the transmission gate and the first internal pin and configured to limit a voltage level of the transmission gate.

7. The packaged integrated circuit as claimed in claim 6, wherein:
in response to the voltage level of the first internal pin being higher than a threshold value, the voltage clamping circuit outputs a specific voltage to the transmission gate, and
in response to the voltage level of the first internal pin not being higher than the threshold value, the voltage clamping circuit outputs the voltage level of the first internal pin to the transmission gate.

8. The packaged integrated circuit as claimed in claim 6, wherein each of the first voltage conversion circuit and the second voltage conversion circuit receives a first operation voltage, each of the storage circuit and the processing circuit receives a second operation voltage, and the first operation voltage is higher than the second operation voltage.

9. The packaged integrated circuit as claimed in claim 8, wherein the voltage clamping circuit receives the second operation voltage and uses the second operation voltage as a threshold value.

10. The packaged integrated circuit as claimed in claim 8, wherein the first chip further comprises:
a power supply circuit configured to generate the second operation voltage; and
a fourth internal pin providing the second operation voltage to the second chip.

11. A bidirectional data transmission method applied in a packaged integrated circuit comprising an input-output pin, comprising:
executing program code to generate an execution result, wherein the program code is stored in a storage circuit;
setting an operation mode of an internal pin based on the execution result;
enabling a first voltage conversion circuit to convert a voltage level of the input-output pin in response to the operation mode of the internal pin being a first mode;
enabling a second voltage conversion circuit to convert the voltage level of the input-output pin in response to the operation mode of the internal pin being a second mode; and
enabling a data transmission circuit to form a transmission path between the internal pin and the input-output pin in response to the operation mode of the internal pin being a third mode,
wherein the first voltage conversion circuit, the second voltage conversion circuit and the data transmission circuit are coupled between the internal pin and the input-output pin.

12. The bidirectional data transmission method as claimed in claim 11, further comprising:
disabling the second voltage conversion circuit and the data transmission circuit in response to the operation mode of the internal pin being the first mode,
disabling the first voltage conversion circuit and the data transmission circuit in response to the operation mode of the internal pin being the second mode, and
disabling the first voltage conversion circuit and the second voltage conversion circuit in response to the operation mode of the internal pin being the third mode.

13. The bidirectional data transmission method as claimed in claim 11, wherein the step of enabling the data transmission circuit in response to the operation mode of the internal pin being the third mode comprises:
turning on a transmission gate;
clamping a voltage level received by the transmission gate.

14. The bidirectional data transmission method as claimed in claim 13, wherein the step of clamping the voltage level received by the transmission gate comprises:
comparing a voltage level of the internal pin and a threshold value;
outputting a specific voltage to the transmission gate in response to the voltage level of the internal pin being higher than the threshold value; and
outputting the voltage level of the internal pin to the transmission gate in response to the voltage level of the internal pin not being higher than the threshold value.

15. The bidirectional data transmission method as claimed in claim 14, further comprising:
providing a first operation voltage to the first voltage conversion circuit and the second voltage conversion circuit;
providing a second operation voltage to the storage circuit,
wherein the first operation voltage is higher than the second operation voltage.

16. The bidirectional data transmission method as claimed in claim 15, wherein the threshold value is equal to the second operation voltage.

17. A control system comprising:
an external device; and
a packaged integrated circuit coupled to the external device and comprising:
an input-output pin electrically connected to the external device;
a micro-controller chip comprising an internal pin; and
a voltage conversion chip comprising a first path, a second path, and a third path, wherein the first path, the second path, and the third path are connected in parallel between the internal pin and the input-output pin,
wherein:
in response to the internal pin serving as an input pin, the micro-controller chip turns on the first path,
in response to the internal pin serving as an output pin, the micro-controller chip turns on the second path,
in response to a voltage level of the internal pin being in a floating state, the micro-controller chip turns on the third path.

18. The control system as claimed in claim 17, wherein the first path comprises a first voltage conversion circuit which converts a voltage level of the input-output pin to generate a first converted level and provides the first converted level to the internal pin.

19. The control system as claimed in claim 18, wherein the second path comprises a second voltage conversion circuit which converts the voltage level of the internal pin to generate a second converted level and provides the second converted level to the input-output pin.

20. The control system as claimed in claim 17, wherein the third path comprises a data transmission circuit which transmits a voltage level of the input-output pin to the internal pin or transmits the voltage level of the internal pin to the input-output pin.
